(19) United States
(12) Patent Application Publication
(10) Pub. No.: US 2015/0301119 A1
(43) Pub. Date: Oct. 22, 2015

(54) BATTERY SENSOR FOR VEHICLE AND METHOD FOR DETERMINING SEASON USING BATTERY SENSOR FOR VEHICLE

(71) Applicant: HYUNDAI MOBIS CO., LTD, Seoul (KR)

(72) Inventor: Soon Keun KWON, Suwon-si (KR)

(73) Assignee: HYUNDAI MOBIS CO., LTD, Seoul (KR)

(21) Appl. No.: 14/691,633

(22) Filed: Apr. 21, 2015

(30) Foreign Application Priority Data
Apr. 22, 2014 (KR) 10-2014-004813

(51) Int. Cl. G01R 31/36; B60L 11/18

(52) U.S. Cl. CPC G01R 31/3648; G01R 31/3627; G01R 31/3675; B60L 11/1851

(57) ABSTRACT

A season is determined by using a battery sensor for a vehicle, and as a result, a performance of a battery is predicted in advance to improve a monitoring performance of the battery sensor for the vehicle.

### CROSS-REFERENCE TO RELATED APPLICATIONS

This application claims priority under 35 U.S.C. §119 to Korean Patent Application No. 10-2014-0048135, filed on Apr. 22, 2014, in the Korean Intellectual Property Office, the disclosure of which is incorporated herein by reference in its entirety.

### TECHNICAL FIELD

The present invention relates to a battery sensor for a vehicle, and more particularly, to a method for determining a season using the battery sensor for the vehicle.

### BACKGROUND

Recently, in vehicles, various electronic control devices, multimedia devices, and the like have been basically installed.

The devices operate according to power supply of a vehicle's battery and thus it is important to manage the vehicle's battery.

In order to manage performance of the vehicle's battery, in the vehicle, a vehicle battery sensor that measures the vehicle battery state is provided. The vehicle battery sensor measures battery performances such as a charge state, the aging degree, and restarting capability of the vehicle battery.

It is well-known that the vehicle battery performance is closely related with a change in a temperature according to the season. Accordingly, the vehicle battery sensor needs to monitor the vehicle battery performance to which the change in temperature according to the season is reflected.

To this end, the vehicle battery sensor needs to automatically determine a current season. However, the vehicle battery sensor having the season determining function is not yet developed.

### SUMMARY

Therefore, the present invention has been made in an effort to provide a battery sensor for a vehicle that determines a season.

The present invention has also been made in an effort to provide a method for determining a season using the battery sensor for the vehicle.

An exemplary embodiment of the present invention provides a battery sensor for a vehicle, including: a prior learning unit classifying daily temperature data into multiple pattern clusters representing seasons to configure a self-organizing map and generating center values of the multiple pattern clusters shown in the self-organizing map as prior-learned seasonal pattern data; a temperature sensing unit measuring outdoor temperature data of the vehicle in real time; and a season classifying unit clustering the outdoor temperature data measured in real time into multiple clusters in accordance with cluster analysis, calculating a center value of the multiple clusters which are clustered, and detecting the pattern cluster having the center value closest to the center value of the multiple clusters by mapping the calculated center value of the multiple clusters to the self-organizing map to classify the season represented by the detected pattern cluster as a current season.

Another exemplary embodiment of the present invention provides a method for determining a season by using a battery sensor for a vehicle, which measures a vehicle battery state, including: configuring a self-organizing map by classifying daily temperature data into multiple pattern clusters representing seasons; generating a center value the multiple pattern clusters shown in the self-organizing map as prior-learned seasonal pattern data; clustering vehicle outdoor temperatures measured in real time into multiple clusters by using cluster analysis and calculating the center value of the multiple clusters; detecting the pattern cluster having the center value closest to the center value of the multiple clusters by mapping the center value of the multiple clusters to the self-organizing map; and classifying seasonal information represented by the detected pattern cluster as current season information.

According to the exemplary embodiments of the present invention, the season is determined by using the battery sensor for the vehicle to further improve a monitoring performance of the battery sensor for the vehicle.

Other features and aspects will be apparent from the following detailed description, the drawings, and the claims.

### BRIEF DESCRIPTION OF THE DRAWINGS

FIG. 1 is a block diagram illustrating an entire vehicle system including a battery sensor for a vehicle according to an exemplary embodiment of the present invention.

FIG. 2 is a block diagram schematically illustrating an internal configuration of the season determining module illustrated in FIG. 1.

FIG. 3 is a configuration diagram illustrating a configuration of an artificial neural network usable in a prior learning unit according to an exemplary embodiment of the present invention.

FIG. 4 is a diagram for describing a propagation rule of the artificial neural network usable in the prior learning unit according to the exemplary embodiment of the present invention.

FIG. 5 is a diagram for describing a learning rule of the artificial neural network usable in the prior learning unit according to the exemplary embodiment of the present invention.

FIG. 6 is a flowchart illustrating a prior learning process performed by the prior learning unit illustrated in FIG. 2.

FIG. 7 is a graph illustrating one example of daily average temperature data used by the prior learning unit illustrated in FIG. 2.

FIG. 8 is a graph for describing histogram data converted according to the exemplary embodiment of the present invention.

FIG. 9 is a graph illustrating one example of a center position value of respective pattern clusters before starting a prior learning according to the exemplary embodiment of the present invention.

FIG. 10 is a graph illustrating one example of a center position value of respective pattern clusters moved after completing the prior learning according to the exemplary embodiment of the present invention.

FIG. 11 is a diagram illustrating prior-learned seasonal pattern data stored in a storage unit according to the exemplary embodiment of the present invention.

FIG. 12 is a flowchart illustrating a process of classifying seasons in a season classifying unit illustrated in FIG. 2.

FIG. 13 is a graph illustrating outdoor temperature data of a vehicle, which is input in the season classifying unit according to the exemplary embodiment of the present invention.

FIG. 14 is a diagram illustrating one example of histogram data converted from the outdoor temperature data of the vehicle illustrated in FIG. 13.

FIG. 15 is a diagram illustrating a center position value of the outdoor temperature data of the vehicle, which is calculated through a K-means algorithm according to the exemplary embodiment of the present invention.

FIG. 16 is a diagram schematically illustrating a season classifying process performed in S1240 of FIG. 12.

FIG. 17 is a diagram illustrating a cluster in the vehicle, which displays seasonal information received from the season classifying unit illustrated in FIG. 2.

### DETAILED DESCRIPTION OF EMBODIMENTS

Hereinafter, exemplary embodiments of the present invention will be described in detail with reference to the accompanying drawings.

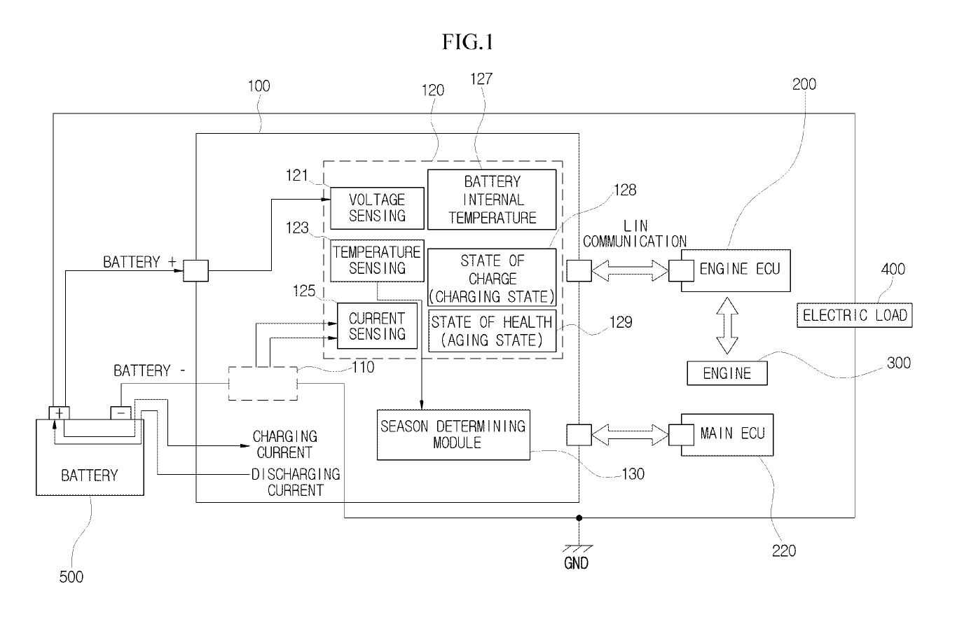

FIG. 1 is a block diagram illustrating an entire vehicle system including a battery sensor for a vehicle according to an exemplary embodiment of the present invention.

Referring to FIG. 1, the entire vehicle system includes a vehicle battery sensing module 100 sensing an internal temperature and a charging state of a vehicle battery 500 and sensing an outdoor temperature of the vehicle to determine a season, an engine ECU 200 receiving internal temperature information and charging state information of the vehicle battery 500 from the vehicle battery sensing module 100 through local interconnect network (LIN) communication and controlling an engine according to the received internal temperature information and charging state information, an engine 300 controlled by the engine ECU 200, a main ECU 220 receiving seasonal data (alternatively, seasonal information) determined by the vehicle battery sensing module 100 through the LIN communication, and an electric load 400 constituted by various in-vehicle electric devices receiving power from the vehicle battery 500.

Since the remaining components 200, 300, and 400 other than the vehicle battery sensing module 100 among the components provided in the entire vehicle system are widely known components, a description thereof will be omitted.

The main ECU 220 transfers the seasonal data received from the vehicle battery sensing module 100 to various in-vehicle electric devices.

The main ECU 220 may control a vehicle cluster so as for a driver to visually verify the seasonal data by transferring the seasonal data to a cluster device of the vehicle.

The driver may determine whether the vehicle is idle upon initial starting or a tire replacement time depending on the season from the seasonal data displayed on the vehicle cluster.

Hereinafter, the vehicle battery sensing module 100 will be described in detail.

The vehicle battery sensing module 100 determines a current season by collecting the outdoor temperature of the vehicle.

The vehicle battery sensing module 100 is electrically connected to each of a (+) terminal of the battery 500 and a (−) terminal of the battery 500 through a shunt resistor 110.

The vehicle battery sensing module 100 includes a calculation module 120 sensing an internal temperature and a charging state of the vehicle battery 500 and a season determining module 130 determining the season.

The calculation module 120 includes a voltage sensing unit 121 measuring a voltage of the battery 500, a temperature sensing unit 123 measuring the internal temperature and the vehicle outdoor temperature of the sensor module 100 in real time, a current sensing unit 125 measuring a current that flows on the vehicle battery 500 according to a difference in voltage between both terminals of the shunt resistor 110, a battery internal temperature analyzing unit (battery temp model (BTM)) 127 analyzing the internal temperature of the vehicle battery 500 based on the internal temperature, a charging state analyzing unit (state of charge (SOC) 128 analyzing the charging state of the battery 500 based on the measured battery voltage and battery current, and an aging state analyzing unit (state of health (SOH)) analyzing an aging state of the battery 500 based on the internal temperature, the battery voltage, and the battery current.

Information on the battery internal temperature, charging state, and aging state analyzed by the respective components 127, 128, and 129 of the calculation module 120 is transferred to the engine ECU 200 through the LIN communication. The engine ECU 200 controls the engine based on each received information.

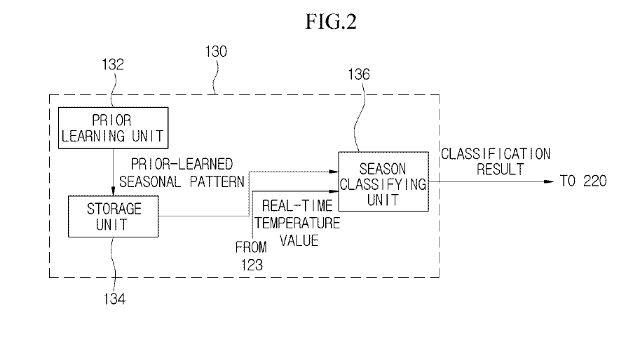

The season determining module 130 acquires seasonal data representing the current season by using prior learned seasonal pattern data. A detailed description thereof will be described below in detail with reference to FIG. 2 given below.

FIG. 2 is a block diagram schematically illustrating an internal configuration of the season determining module illustrated in FIG. 1.

Referring to FIG. 2, the season determining module 130 includes a prior learning unit 132 learning the seasonal pattern data, a storage unit 134 storing the seasonal pattern data prior-learned by the prior learning unit 132, and a season classifying unit 136 classifying the seasons by using the prior-learned seasonal pattern data stored in the storage unit 134.

The prior learning unit 132 receives previous-year daily temperature data and learns the daily temperature data by using a self-organizing map (SOM) to generate the prior-learned seasonal pattern data.

The prior-learned seasonal pattern data is stored in the storage unit 134.

The season classifying unit 136 classifies the seasons by using the vehicle outdoor temperature data and prior-learned seasonal pattern data measured, in real time, by the temperature sensing unit 123.

The classified seasonal data is transferred to the main ECU 220 and the main ECU 220 processes the received seasonal data and transfers the processed seasonal data to the corresponding in-vehicle electronic device requesting the seasonal data.

Hereinafter, a prior learning process of the seasonal pattern data performed by the prior learning unit 132 will be described in detail.

The prior learning unit 132 learns the seasonal pattern data by using the self-organizing map (SOM).

The self-organizing map (SOM) is one of self-learning methods using an artificial neural network.

Self-organizing represents not providing an accurate output pattern for a pattern of input information, but clustering the pattern of the input information and learning any specific output pattern from a clustered result.

The artificial neural network will be introduced in brief in order to help understand the learning process of the seasonal pattern data.

Artificial Neural Network

The artificial neural network models a method of a biological neural system recognizing an object or event and mathematically uses and processes the modeled method. That is, in the case of the artificial neural network, the artificial neural network completing learning of an input pattern may induce a correct output pattern even with respect to an unlearned input pattern.

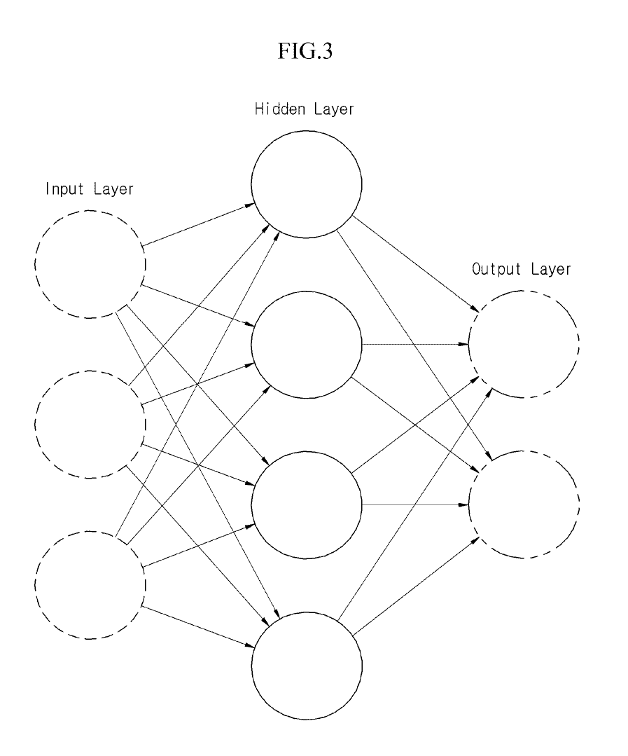

FIG. 3 is a configuration diagram illustrating a configuration of an artificial neural network usable in a prior learning unit according to an exemplary embodiment of the present invention.

As illustrated in FIG. 3, the artificial neural network includes an input layer, a hidden layer, and an output layer.

The input layer means a data input for learning and the output layer means an output of a learning result value. In addition, the hidden layer means propagation, learning, and activation of information.

Propagation Rule of Artificial Neural Network

The propagation rule of the artificial neural network means a rule by which a new state may be acquired from a current state in a system by combining input patterns of the system.

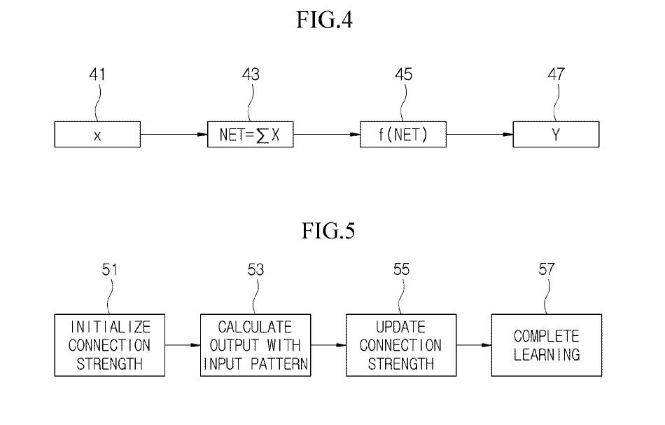

FIG. 4 is a diagram for describing a propagation rule of the artificial neural network usable in the prior learning unit according to the exemplary embodiment of the present invention.

As illustrated in FIG. 4, according to the propagation rule of the artificial neural network, an input block 41 of the system receives an input pattern X and transfers the received input pattern X to a sigma calculation block 43. The sigma calculation block 43 calculates a sum (NET=ΣX) of the received input patterns X and transfers the calculation result to an activation function block 45. The activation function block 45 combines the sum (NET, threshold weight) of the received input patterns by using an activation function (f( )) and transfers the combination result (f(NET)) to an output block 47. The output block 47 outputs the received combination result (f(NET)) according to the rule (Y=f(NET)) to acquire the new state from the current state.

Activation Rule of Artificial Neural Network

The activation rule of the artificial neural network means a threshold rule in which the input weight of data input in the artificial neural network influences an output. The activation rule may be expressed as follows. If (NET>T) Y=1, ELSE Y=0, wherein, NET represents the threshold weight, T represents a threshold, and Y represents the activation function.

Learning Rule of Artificial Neural Network

The learning rule of the artificial neural network represents a process of adopting a connection strength between neurons to be suitable for a specific application purpose.

FIG. 5 is a diagram for describing the learning rule of the artificial neural network performed by the prior learning unit according to the exemplary embodiment of the present invention.

As illustrated in FIG. 5, the learning rule of the artificial neural network includes a process 51 of initializing a connection strength, a process 53 of calculating an output with an input pattern, a process 55 of updating the connection strength, and a process 57 of completing learning.

The self-organizing map (SOM) used to prior-learn the seasonal pattern data in the prior learning unit 132 of FIG. 2 is generated by using an artificial neural network algorithm constituted by the propagation rule of the artificial neural network, the activation rule, and the learning rule of the artificial neural network described above.

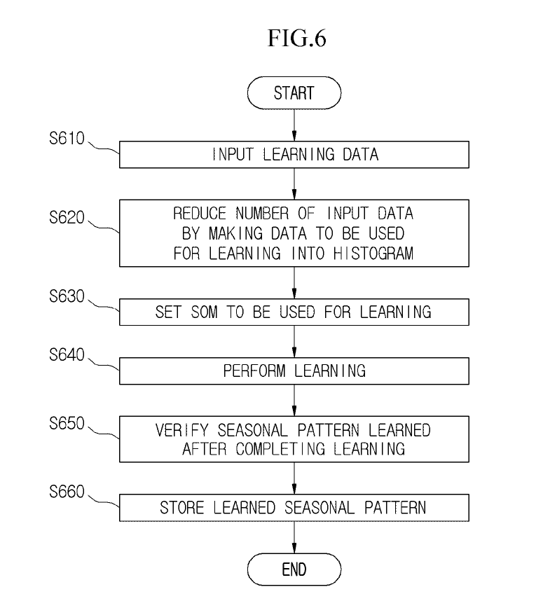

Hereinafter, a process of learning the seasonal pattern data using the SOM performed by the prior learning unit will be described with reference to FIG. 6.

FIG. 6 is a flowchart illustrating a prior learning process performed by the prior learning unit illustrated in FIG. 2.

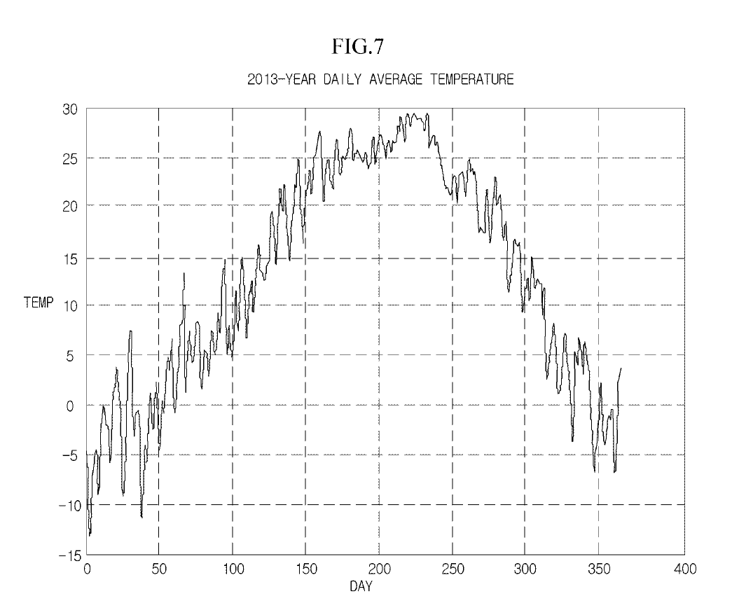

Referring to FIG. 6, first, in step S610, a process of receiving learning data is performed. The learning data is assumed as 2013-year daily temperature data as illustrated in FIG. 7.

In S620, in order to reduce a prior learning processing time, a process of changing the received 2013-year daily temperature data into histogram data is performed.

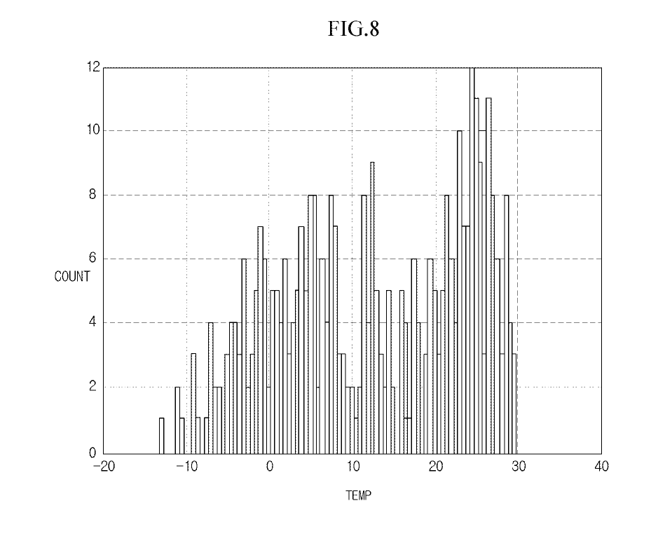

The process of changing the daily temperature data to the histogram data includes a process of setting multiple temperature intervals and a process of changing daily temperature data corresponding to each set temperature interval to the histogram data having a bar graph shape as illustrated in FIG. 8. The daily temperature data is changed to the histogram data to reduce the number of data used in the prior learning.

In S630, a process of setting the self-organizing map (SOM) to be used to learn the changed histogram data is performed. That is, a process of setting the neuron used in the hidden layer illustrated in FIG. 3 is performed.

A change in temperature data depending on a seasonal change has a consecutive characteristic. By considering the consecutive characteristic, an example of setting five neurons constituted by winter, winter/autumn, autumn/spring, spring/summer, and summer is described in the exemplary embodiment.

In the exemplary embodiment, an example of setting pattern clusters determining the season as five neurons constituted by winter, winter/autumn, autumn/spring, spring/summer, and summer is described by considering a consecutive change characteristic of temperature data depending on a seasonal change.

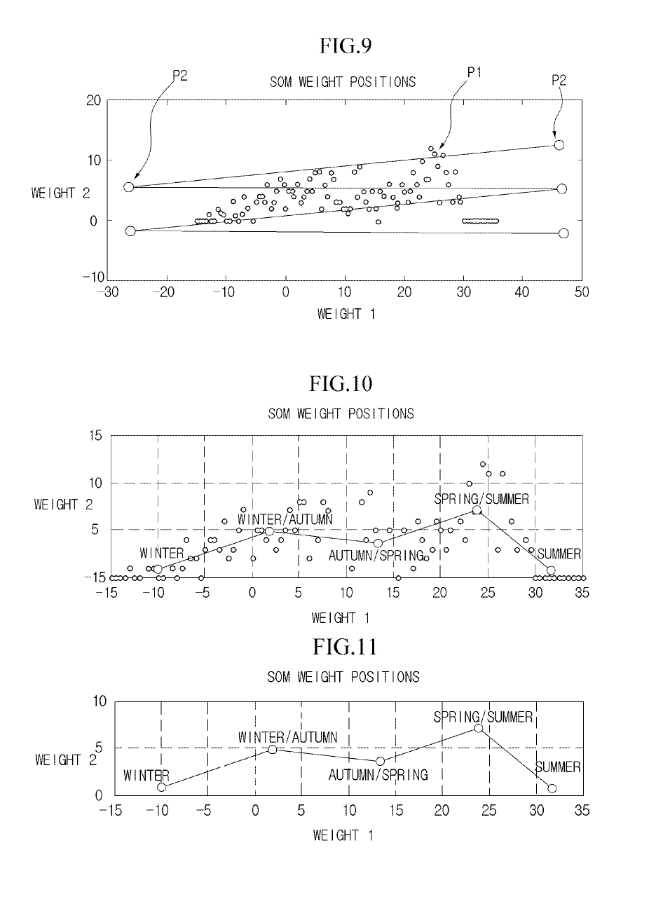

The self-organizing map (SOM) in which five neurons constituted by winter, winter/autumn, autumn/spring, spring/summer, and summer are set is illustrated in FIG. 9.

In FIG. 9, as a graph showing the position of a center (weight or connection strength) of a pattern cluster before learning, Weight 1 of an x axis represents temperature and Weight 2 of a y axis represents a count of histogram data counted for each temperature.

In FIG. 9, points P1 having a small size and 5 points P2 having a relatively large size are illustrated.

The points P1 are the histogram data and 5 points P2 are pattern clusters constituted by winter, winter/autumn, autumn/spring, spring/summer, and summer before learning.

In S640, a learning process of the histogram data is performed by using the SOM set in S630. Repeated execution of the number of learning times improves accuracy of a learning result. In the exemplary embodiment, a learning process may be performed approximately 1000 times.

When the learning processes are completed, in S650a process of verifying a learned seasonal pattern after completing the learning is performed.

The verification process is a process of verifying a center position value (weight position or connection strength) of each moved pattern cluster at the time when the learning is completed. In FIG. 10, the center position value of each pattern cluster moved after the learning process is performed at 1000 times is illustrated.

In S660, a process of storing the verified center position values of the respective pattern clusters in the storage unit 134 illustrated in FIG. 2 is performed. For example, when the verified center position value of each pattern cluster is as illustrated in FIG. 11, the prior-learned seasonal pattern data (alternatively, prior-learned seasonal pattern coordinate data) may be expressed by Table 1 given below.

TABLE 1

| | Weight 1 | Weight 2 |
|---|---|---|
| Winter | −10.1500 | 0.8500 |
| Winter/autumn | 1.7500 | 4.9167 |
| Autumn/spring | 13.2857 | 3.6190 |
| Spring/summer | 23.7778 | 7.1667 |
| Summer | 31.5769 | 0.7692 |

### [Seasonal Pattern Data or Seasonal Pattern Data Coordinate]

As such, when the seasonal pattern data prior-learned by the prior learning unit 132 is acquired through the processes of FIG. 6, a process of classifying the seasons corresponding to the vehicle outdoor temperature measured by the vehicle battery sensor is performed in the season classifying unit 136 of FIG. 2 based on the acquired prior-learned seasonal pattern data.

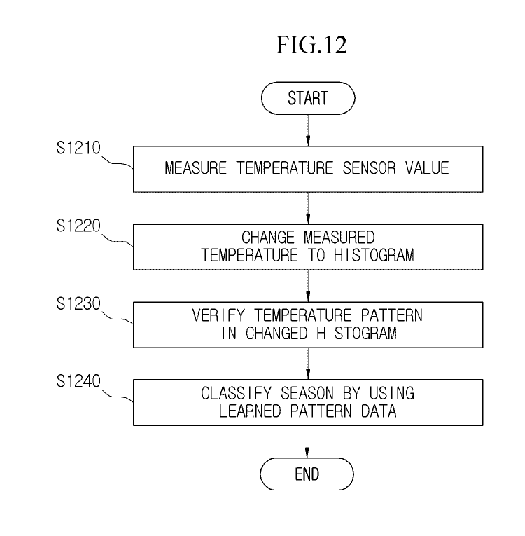

Hereinafter, the process of classifying the seasons by using the seasonal pattern data prior-learned up to now will be described in detail with reference to FIG. 12.

FIG. 12 is a flowchart illustrating a process of classifying seasons in the season classifying unit 136 illustrated in FIG. 2. Unless particularly mentioned, as an execution agent of each step given below, the season classifying unit 136 illustrated in FIG. 2 is assumed.

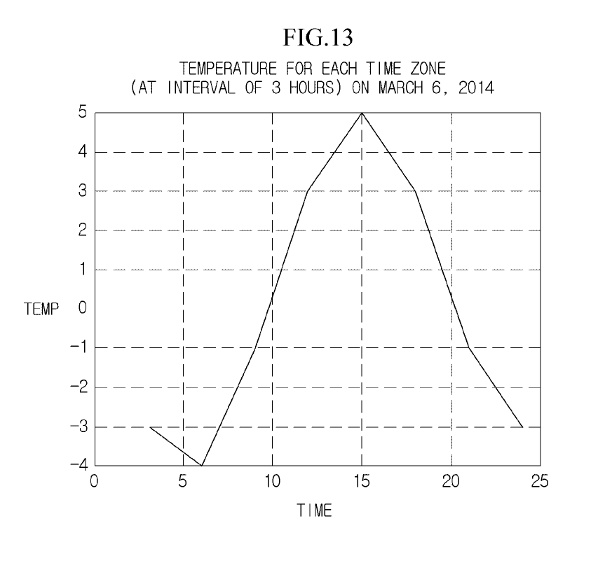

Referring to FIG. 12, in step S1210, the temperature sensing unit 123 of the vehicle battery sensor 100 measures the vehicle outdoor temperature in real time. For example, as illustrated in FIG. 13, the temperature sensing unit 123 in the vehicle battery sensor measures the vehicle outdoor temperature on Mar. 6, 2014 in real time at a time interval of 3 hours. For accurate measurement, the vehicle outdoor temperature is preferably measured while the vehicle stops. When the vehicle outdoor temperature is measured while the vehicle is driven, since the temperature sensing unit 123 may be influenced by an engine temperature, the vehicle outdoor temperature may not be accurately measured.

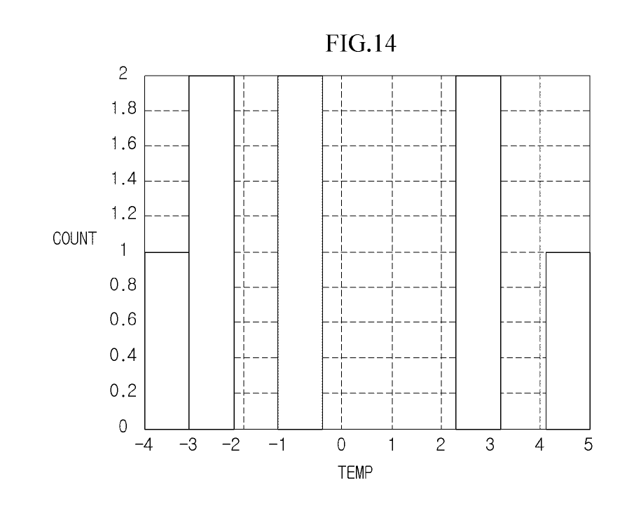

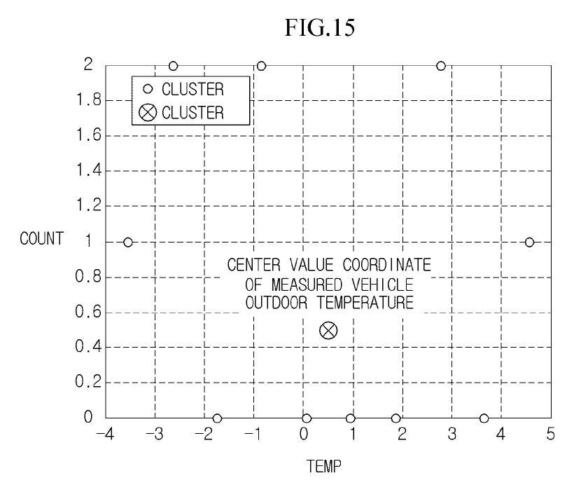

In S1220, a profile of the vehicle outdoor temperature measured in real time by the temperature sensing unit 123 is input in the season classifying unit 136 of the season determining module 130. The season classifying unit 136 performs a process of changing the profile of the vehicle outdoor temperature measured in real time to the histogram data having the bar graph shape as illustrated in FIG. 14.

In S1230, a process of verifying a temperature pattern of the vehicle outdoor temperature measured by using cluster analysis for the changed histogram data is performed. The verification process is a process of clustering similar histogram data into multiple clusters and calculating a center value of the multiple clusters.

In S650 of FIG. 6, the center position value (weight position or connection strength) of each pattern cluster is verified by the self-organizing map (SOM) algorithm in S650 of FIG. 6, but herein, since the temperature pattern of the measured vehicle outdoor temperature needs to be verified in real time, the center value of the clusters needs to be verified by using an algorithm having a smaller processing quantity than the SOM algorithm. For example, a center value of the clusters of the vehicle outdoor temperature clustered may be calculated by using a K-means clustering algorithm.

FIG. 15 is a diagram illustrating the center value of the clusters of the vehicle outdoor temperature calculated by using the K-means clustering algorithm.

FIG. 15 illustrates an example in which a coordinate of the center value of the vehicle outdoor temperature is 0.5000, 0.5000.

In S1240, a process is performed, which classifies the current season by comparing the center value of the vehicle outdoor temperature calculated in S1230 with the seasonal pattern prior-learned in FIG. 6. In the K-means clustering algorithm, by comparing distances between the input data (center value coordinate of the vehicle outdoor temperature) and the center values (alternatively, center value coordinates) of the prior-learned pattern clusters, a closest pattern cluster is allocated as the input data. After the allocation, a center value coordinate of a new pattern cluster is calculated by using the input data and the center value coordinate of each prior-learned pattern cluster and the calculated center value coordinate is updated.

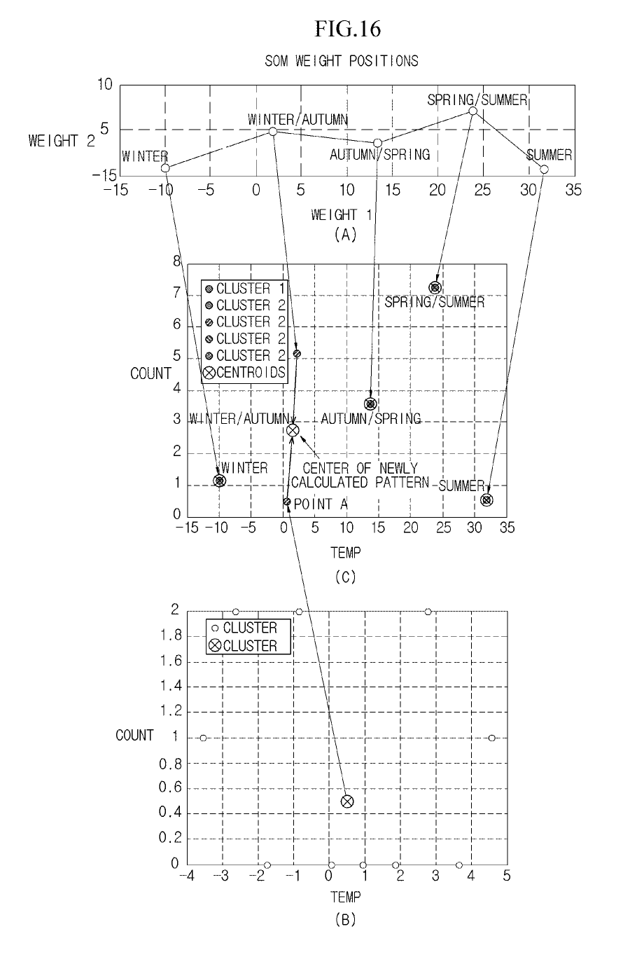

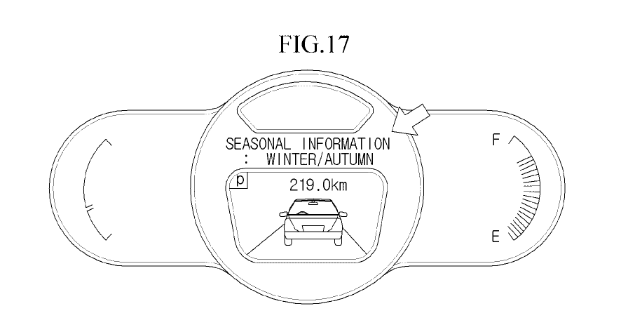

FIG. 16 is a diagram schematically illustrating the season classifying process performed in S1240 of FIG. 12.

FIG. 16A illustrates the prior-learned seasonal pattern described in FIG. 6 and FIG. 16B illustrates the center value of the vehicle outdoor temperature calculated by applying the K-means clustering algorithm to the vehicle outdoor temperature data measured through the temperature sensing unit in the vehicle battery sensor. In addition, FIG. 16C illustrates a result of classifying the current season by using the K-means clustering algorithm with respect to the center value of the prior-learned seasonal pattern data of FIG. 16A and the cluster (the center value of the clustered vehicle outdoor temperature) of FIG. 16B.

As illustrated in FIG. 16C, the center value of the vehicle outdoor temperature measured in real time and the center value coordinate of the prior-learned seasonal pattern data are mapped to one coordinate axis illustrated in FIG. 16C. Thereafter, the distances between the center value coordinate of the vehicle outdoor temperature and the center values (alternatively, center value coordinates) of each prior-learned pattern cluster are compared and a pattern cluster closest to the center value coordinate (point A) of the vehicle outdoor temperature is selected. FIG. 16C illustrates an example in which ‘winter/autumn’ is selected as the pattern cluster closest to the center value coordinate (point A) of the vehicle outdoor temperature. When the pattern cluster is selected, the center value coordinate of the new pattern cluster, ‘winter/autumn’ is calculated by using the center value coordinate of each prior-learned pattern cluster to update the prior-learned pattern cluster corresponding to ‘winter/autumn’ as the center value coordinate of the new pattern cluster ‘winter/autumn’

As such, when the center value of the vehicle outdoor temperature measured in real time by the vehicle battery sensor is used as the input of the prior-learned seasonal pattern, it can be verified that the center value is allocated to the pattern cluster corresponding to ‘winter/autumn’ as described above. Therefore, the vehicle battery sensor finally determines ‘winter/autumn’ as the current season. The determined season data is transferred to the main ECU 220 of FIG. 1 through a communication channel in the vehicle. The main ECU displays the season data received from the vehicle battery sensor on the vehicle cluster to help a user to prepare for a driving state suitable for the season as illustrated in FIG. 17. For example, the user may determine whether the vehicle is idle upon initial starting or a tire replacement time depending on the season from the seasonal information displayed on the cluster.

The present invention may not limitatively adopt the configurations and methods of the exemplary embodiments as described, but all or some of the respective exemplary embodiments may be selectively combined and configured so that the exemplary embodiments may be variously modified.

What is claimed is:

1. A battery sensor for a vehicle, which measures a vehicle battery state, the sensor comprising:
a prior learning unit classifying daily temperature data into multiple pattern clusters representing seasons to configure a self-organizing map and generating center values of the multiple pattern clusters shown in the self-organizing map as prior-learned seasonal pattern data;
a temperature sensing unit measuring outdoor temperature data of the vehicle in real time; and
a season classifying unit clustering the outdoor temperature data measured in real time into multiple clusters in accordance with cluster analysis, calculating a center value of the multiple clusters which are clustered, and detecting the pattern cluster having the center value closest to the center value of the multiple clusters by mapping the calculated center value of the multiple clusters to the self-organizing map to classify the season represented by the detected pattern cluster as a current season.

2. The sensor of claim 1, wherein the prior learning unit sets multiple pattern clusters as neurons used in a hidden layer of an artificial neural network to configure the self-organizing map.

3. The sensor of claim 2, wherein the prior learning unit sets the multiple pattern clusters as multiple neurons representing a consecutive change characteristic of temperature data depending on a seasonal change to configure the self-organizing map.

4. The sensor of claim 3, wherein the multiple neurons include winter, winter/autumn, autumn/spring, spring/summer, and summer.

5. The sensor of claim 1, wherein the temperature sensing unit measures the outdoor temperature data in real time when the vehicle stops.

6. The sensor of claim 1, wherein the season classifying unit changes the outdoor temperature data to histogram data, clusters the histogram data into the multiple clusters by using the cluster analysis, and calculates the center value of the multiple clusters.

7. The sensor of claim 6, wherein the cluster analysis is based on a K-means clustering algorithm.

8. The sensor of claim 1, wherein the season classifying unit transfers the information to a cluster in the vehicle in order to visually display information representing the classified seasons.

9. A method for determining a season by using a battery sensor for a vehicle, which measures a vehicle battery state, the method comprising:
configuring a self-organizing map by classifying daily temperature data into multiple pattern clusters representing seasons;
generating a center value the multiple pattern clusters shown in the self-organizing map as prior-learned seasonal pattern data;
clustering vehicle outdoor temperatures measured in real time into multiple clusters by using cluster analysis and calculating the center value of the multiple clusters;
detecting the pattern cluster having the center value closest to the center value of the multiple clusters by mapping the center value of the multiple clusters to the self-organizing map; and
classifying seasonal information represented by the detected pattern cluster as current season information.

10. The method of claim 9, wherein the configuring of the self-organizing map includes setting multiple pattern clusters as neurons used in a hidden layer of an artificial neural network.

11. The method of claim 10, wherein in the setting as the neurons, the multiple pattern clusters are set as multiple neurons representing a consecutive change characteristic of temperature data depending on a seasonal change.

12. The method of claim 11, wherein the multiple neurons include winter, winter/autumn, autumn/spring, spring/summer, and summer.

13. The method of claim 9, wherein the calculating the center value of the multiple clusters includes
measuring the vehicle outdoor temperature data in real time when the vehicle stops,
changing the vehicle outdoor temperature measured in real time to histogram data, and
clustering the histogram data into multiple clusters by using the cluster analysis and calculating the center value of the multiple clusters.

14. The method of claim 13, wherein the cluster analysis is based on a K-means clustering algorithm.

15. The method of claim 9, further comprising:
after the classifying as the current seasonal information,
transferring the classified seasonal information to a cluster in the vehicle; and
visually displaying the classified seasonal information on the cluster in the vehicle.
